(19) United States
(12) Patent Application Publication
(10) Pub. No.: US 2024/0397638 A1
(43) Pub. Date: Nov. 28, 2024

(54) HIGH VOLTAGE CONNECTOR THERMAL CRASH AND VIBRATION SHIELD

(71) Applicant: Garrett Transportation I Inc., Torrance, CA (US)

(72) Inventor: Valeriy Fedorikhin, Redondo Beach, CA (US)

(73) Assignee: Garrett Transportation I Inc., Torrance, CA (US)

(21) Appl. No.: 18/324,176

(22) Filed: May 26, 2023

(51) Int. Cl. H05K 5/00; H01R 13/53; H01R 13/533; H01R 13/56; H05K 7/20; H05K 9/00

(52) U.S. Cl. CPC H05K 5/0069; H01R 13/53; H01R 13/533; H01R 13/567; H05K 7/20872; H05K 9/0015

(57) ABSTRACT

A thermal and vibrational management system for providing an electrical cable support and heat shield including a cable clamping device for clamping to a portion of an electrical cable and a rigid tubular sleeve having a connector end and a clamping end and an interior dimension configured to receive the electrical cable, wherein the connector end is mechanically coupled to a cooled structure and the clamping end is configured with the cable clamping device.

### TECHNICAL FIELD

The present disclosure generally relates to a thermal and vibration protective electrical connection and, more particularly, relates to a thermally conductive shield including a cable restraint device for mechanically coupling to an electronic product enclosure such that the electric cable and connector are thermally protected and restrained from excessive vibration.

### BACKGROUND

A problem exists in high voltage and high temperature applications that plastic connectors may fail, or have reduced efficacy due to vibration and high ambient temperatures. In vehicle engine applications, high temperatures generated by engine exhaust result can result in thermal damage to electronic components, printed circuit boards and electrical system cables and wiring harnesses. When connectors overheat, they can melt, deform, or even catch fire. This can damage the motor, the connector, and other equipment in the circuit. For example, high heat may melt electrical connector where they come in close proximity to metallic surfaces thereby reducing the current rating of the connector and/or premature connector failure.

Typical automotive electrical connectors rely on spring contacts in electrical plugs and sockets in order to make an easily removable and re-usable connection. These spring connections makes contact between the two sides of the connector and rely on spring force to maintain that connection. In high current applications, the contact point has very limited area so heat can build up at these contact points. In addition, cost effective plastic connector housings are susceptible to damage during a crash, resulting in a high risk of exposing high voltage and current electrical contacts.

An addition problem with spring pin connections in automotive applications is that the spring pin connections within a connector may lose conductive coatings due to abrasion caused by vibration. Typically, both the spring connector and the terminal it is pressed against are plated with a highly conductive metal, such as tin, gold, silver etc. to prevent against corrosion and oxidation which increase connection resistance values. These plating metals are also typically soft metals which can be prone to wear. In a high vibration automotive application, the subtle movement of the part or the cable which the connector is attached to leads to small relative movement between the spring contact and its mating terminal, thereby wearing the terminal plating, leading to spikes in contact resistance and heat generated as a result. Thus, it is desirable to provide increased thermal and vibration protection to these cost effective plastic connections while preventing connector damage during vehicle crashes or other vehicle damage occurrences. Other desirable features and characteristics of the present disclosure will become apparent from the subsequent detailed description and the appended claims, taken in conjunction with the accompanying drawings and this background discussion.

### BRIEF SUMMARY

The present disclosure provides calibration systems and methods for a providing an electrical cable connection in an automotive application with enhanced vibration and thermal protections. The exemplary system is configured with a rigid thermal shield coupled to rigid, liquid cooled, electronics enclosure at a first end and a cable clamp at the second end a distance away from the first end, wherein the cable runs through the rigid thermal shield and wherein the cable includes an electrical connector proximate to the first end, mechanically coupled to an electronic component within the electronics enclosure. In accordance with an exemplary embodiment, an electric vehicle thermal management system including an electrical cable support and heat shield, a cable clamping device for clamping to a portion of an electrical cable, and a rigid tubular sleeve having a connector end and a clamping end and an interior dimension configured to receive the electrical cable, wherein the connector end is mechanically coupled to a cooled structure and the clamping end is configured with the cable clamping device.

In accordance with another aspect of the exemplary embodiment, wherein a first electrical connector affixed to the electrical cable is mechanically coupled to a corresponding electrical connector within the cooled structure such that the electrical cable is communicatively coupled to an electronic component within the cooled structure.

In accordance with another aspect of the exemplary embodiment, wherein the cooled structure is a metallic electronic enclosure.

In accordance with another aspect of the exemplary embodiment, wherein the cooled structure is a liquid cooled structure.

In accordance with another aspect of the exemplary embodiment, wherein the rigid tubular sleeve includes a flange at the connector end and wherein the flange is mechanically coupled to the cooled structure with a plurality of threaded bolts each passing through a hole in the flange and threaded into a corresponding hole in the cooled structure.

In accordance with another aspect of the exemplary embodiment, wherein the cable clamping device is electrically coupled to a braided shield of the electrical cable and the rigid tubular sleeve is electrically coupled to the cooled structure.

In accordance with another aspect of the exemplary embodiment, wherein the rigid tubular sleeve further includes a plurality of ridges formed on an interior surface of the rigid tubular sleeve.

In accordance with another aspect of the exemplary embodiment, wherein the cooled structure encloses a motor controller and wherein the electrical cable conducts an electrical current between the motor controller and an electric motor.

In accordance with another aspect of the exemplary embodiment, further including an electrically conductive gasket located between the cooled structure and the rigid tubular sleeve.

In accordance with another aspect of the exemplary embodiment, an environmental management system including an electronic enclosure including a printed circuit board having a first electrical connector wherein the first electrical connector aligns with an opening in the electronic enclosure, an electrical cable having a second electrical connector for coupling to the first electrical connector, and a tubular cable shield having a flange end and a clamping end wherein the second electrical connector is positioned within the flange end and wherein the flange end is mechanically affixed over the opening in the electronic enclosure creating an environmental and thermal barrier around the second electrical connector and where the clamping end includes a cable clamp assembly for restraining the electrical cable.

In accordance with another aspect of the exemplary embodiment, including an electronic enclosure of claim 10 further including an electrically conductive gasket located between the flange end of the tubular cable shield and the electronic enclosure.

In accordance with another aspect of the exemplary embodiment, including an electronic enclosure of claim 10 wherein the electronic enclosure is a liquid cooled structure and wherein the tubular cable shield is thermally coupled to the electronic enclosure.

In accordance with another aspect of the exemplary embodiment, including an electronic enclosure of claim 10 wherein the cable clamp assembly restrains the electrical cable at least eight centimeters from the second electrical connector.

In accordance with another aspect of the exemplary embodiment, including an electronic enclosure of claim 10 wherein the cable clamp assembly and the electronic enclosure are both mechanically affixed to a common rigid support.

In accordance with another aspect of the exemplary embodiment, including an electronic enclosure of claim 10 wherein the cable clamp assembly and the electronic enclosure are both mechanically affixed to an engine block component.

In accordance with another aspect of the exemplary embodiment, including an electronic enclosure of claim 10 wherein the cable clamp assembly is electrically coupled to an electromagnetic shield of the electrical cable and wherein the cable clamp assembly is electrically coupled to the electronic enclosure.

In accordance with another aspect of the exemplary embodiment, including an electronic enclosure of claim 10 wherein the tubular cable shield further includes a plurality of protrusions formed on an interior surface of the tubular cable shield such that the plurality of protrusions restrict movement of the electrical cable.

In accordance with another aspect of the exemplary embodiment, including an electronic enclosure of claim 10 further including an electrically conductive gasket located between the electronic enclosure and the flange end of the tubular cable shield.

In accordance with another aspect of the exemplary embodiment, a method of providing an electrical cable support and heat shield including inserting an electrical cable through a tubular cable shield having a flange end and a cable clamping end, affixing a first electrical connector onto the electrical cable protruding from the flange end of the tubular cable shield, coupling the first electrical connector to a second electrical connector positioned in an opening in an electronics enclosure, mechanically affixing the flange end of the tubular cable shield over the opening in the electronics enclosure such that an environmental a barrier is created around the first electrical connector and the second electrical connector, and clamping the electrical cable with a cable clamp assembly affixed to the cable clamping end of the tubular cable shield such that the electrical cable is restrained by the cable clamp assembly.

In accordance with another aspect of the exemplary embodiment, including mechanically affixing the electronics enclosure and the cable clamp assembly to a rigid structure.

### BRIEF DESCRIPTION OF THE DRAWINGS

The present disclosure will hereinafter be described in conjunction with the following drawing figures, wherein like numerals denote like elements, and wherein:

FIG. 1 is illustrative of a cross section an exemplary environment for an improved high voltage connector thermal, crash and vibration cable shield in accordance with various embodiments of the present disclosure;

FIG. 2 illustrates a cross section of an exemplary configuration for an improved high voltage connector thermal, crash and vibration cable shield is shown in accordance with various embodiments of the present disclosure;

FIG. 3 illustrates another a cross sectional view of the cable shield for the improved high voltage connector thermal, crash and vibration cable shield in accordance with various embodiments of the present disclosure; and

FIG. 4 depicts a flow diagram illustrating a non-limiting embodiment of a method 400 of providing an improved high voltage connector thermal, crash and vibration cable shield in accordance with the teachings of the present disclosure.

### DETAILED DESCRIPTION

The following detailed description is merely exemplary in nature and is not intended to limit the present disclosure or the application and uses of the present disclosure. Furthermore, there is no intention to be bound by any theory presented in the preceding background or the following detailed description.

Broadly, example embodiments disclosed herein include an improved high voltage connector thermal crash and vibration shield. The improved high voltage connector thermal crash and vibration shield can include a snug fit metallic tube covering a plastic high voltage cable connector. The shield can be mated to a liquid cooled electronics enclosure to conduct heat from the shield to the electronics enclosure, thereby reducing the temperature of the shield to below the ambient air temperature surrounding the connector. In addition, the cable from the connector can be clamped by a connector integrated with the shield in order to prevent excess cable movement and vibration from transferring to the connector, leading to plating wear on the connector contact points.

Thermal protection is an important safety and reliability feature that can help to prevent fires and equipment damage. Vibration control and thermal protection are important design criteria when combining internal combustion engines within electrical systems. Proper thermal protection and vibration control improves vehicle safety, extends the service life of electric connectors by preventing them from overheating and failing, reduces maintenance costs by preventing costly repairs or replacements of electric connectors, and can help to improve the reliability of electrical systems by preventing failures caused by overheating.

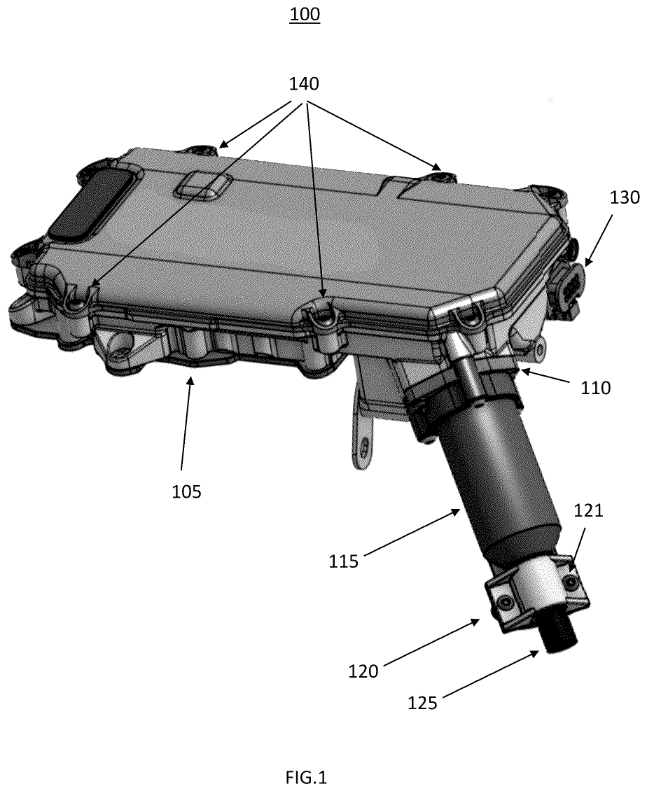

Turning now to FIG. 1, an exemplary environment 100 for an improved high voltage connector thermal, crash and vibration cable shield 115 is shown in accordance with various embodiments. The exemplary environment 100 shows an electronics enclosure 105, a shield 115, a shield gasket 110, a cable clamp 120, a cable 125 and an electric connector 130.

The electronics enclosure 105 can be a metallic, liquid cooled enclosure for containing and protecting electric circuits, printed circuit boards, and other sensitive electronic components. The electronics enclosure 105 can be fabricated from aluminum, copper, or another thermally conductive material. The electronics enclosure 105 can include a top portion and a bottom portion which can be mechanically coupled with fasteners 140, such as screws or bolts. An electronics package, such as a printed circuit board (PCB) or the like can be inserted and affixed inside the electronics enclosure 105 before the top portion and bottom portion are mechanically affixed, Electrical connectors 130 can be aligned with openings in the electronics enclosure 105 to allow electrical power supply and data communications to be supplied to the printed circuit board when the electronics enclosure 105 is installed. In some exemplary embodiments, the electronics enclosure 105 can be affixed to a thermally controlled automotive component, such as an engine block, or battery enclosure such that thermal energy can be transferred from the electronics enclosure 105 to the thermally controlled automotive component.

The electronic enclosure 105 can protect printed circuit boards (PCBs) and electronic components from a variety of environmental factors including moisture, dust, dirt, extreme temperatures, electromagnetic interference and vibration. Metallic enclosures are effective at isolating sensitive electronic components from moisture which can cause corrosion and electrical short. In addition, dust and dirt are prevented from accumulating on the electronics systems. If not protected, dust and dirt can accumulate on the electronic components, causing them to overheat and possibly fail, thereby shortening the life of the components. Metallic enclosures can also shield sensitive electronic circuits from extreme temperatures, both hot and cold, and can be designed with vibrational damping to lessen the risk of damage. In addition, metallic circuit enclosures protect the electronic components and circuits from electromagnetic interference generated by engine ignition systems and other strong electrical current systems from corrupting electronic signals transmitted and received by the electronic components and reducing the chance of damage to the electronic systems by induced electrical currents and the like.

The exemplary environment shows an electrical connector 130 that is not connected to a corresponding cable and another electrical connector that is connected to a cable with a cable shield 115 installed according to an exemplary embodiment. In some exemplary embodiments, both electrical connectors can be configured to enable a cable shield to be installed. The cable shield 115 can include a snug fit metallic tube that gets pressed over the plastic cable connector to serve as an impact protection in case of vehicle crash. The cable shield can be mechanically affixed to the enclosure 105 with one or more bolts which pass through a flange in the cable shield and are threaded into corresponding threaded holes in the enclosure 105. In some exemplary embodiments, configuring the cable shield 115 to be mechanically coupled to the electronic enclosure 105 can allow for thermal energy to be coupled from the cable shield 115 to the electronic enclosure 105. This can allow the cable shield 115 to stay much cooler than the ambient air temp of the engine bay which surrounds the electrical connector and corresponding cable enabling for the connector to conduct higher electric currents without being derated due to high ambient temperatures. The bolted on U clamp on the end holds the cable extending out of the connector towards the battery. this prevents excess cable movement and vibration from transferring to the connector and also leading to plating wear.

In some exemplary embodiments, a gasket 110 may be installed between the cable shield 115 and the electronic enclosure 105. The gasket 110 can be fabricated from a pliable conductive or nonconductive material and is used to maintain the environmental protective barrier between the inside of the electronic enclosure 105 and the ambient environment. The gasket 110 can be formed with a thermally conductive material in order to allow thermal energy to be coupled from the cable shield 115 to the electronic enclosure 105. Likewise, the gasket 110 can be formed from an electrically conductive material, such as woven copper, in order to conduct electricity between the cable shield 115 and the electronic enclosure 105. An electrically conductive gasket material may enable the electrical energy from a ground shield on the cable 125 to be electrically coupled to the cable shield 115 thereby conducting any electrical energy received to the ground shield of the cable 125 within the ambient environment, to be coupled to the electronic enclosure 105 via the cable shield 115 and the electrically conductive gasket 110. This arrangement would enable unwanted electromagnetic interference to be grounded to the engine block via the electronic enclosure 105 rather than being coupled to a ground plane of the PCB within the electronic enclosure 105.

In some exemplary embodiments, material for the gasket 110 can be selected to protect from any potential galvanic effect and related corrosion occurring between dissimilar metals of the electronic enclosure 105 and the cable shield 115. Galvanic corrosion is a type of corrosion that occurs when two dissimilar metals are in electrical contact with each other in the presence of an electrolyte. The electrolyte can be a liquid, such as water, or a gas, such as air. When the two metals are in contact, an electrical current flows between them. This current causes one of the metals to corrode more than the other. The gasket 110 can be designed to limit the galvanic corrosion by providing a barrier between the two metals. The gasket prevents the flow of electrons between the metals, which prevents corrosion. When selecting materials for the gasket 110 to to prevent galvanic corrosion, there are a number of factors that should be considered, including the type of metals that will be in contact with the gasket 110 and the environment in which the gasket will be used and the pressure and temperature at which the gasket 110 will be exposed to. The type of gasket that is selected should be compatible with the type of metals that will be in contact with it. For example, a gasket made of a conductive material should not be used between two dissimilar metals that are in contact with each other in the presence of an electrolyte.

The cable shield 115 can be fitted with a cable clamp 120 for supporting the cable 125 in order to reduce vibrations and torque experienced by the connector as a result of cable movement. In some exemplary embodiments, the cable clamp 120 can include one or more mechanical fasteners 121 for mechanically affixing the cable clamp 120 to another rigid body within the engine compartment environment, such as an engine block, intake manifold, or the like. Ideally, the cable clamp 120 should be affixed to the same component that the electronic enclosure is affixed to in order to reduce deflection and tortional stress between the cable shield 115 and the electronic enclosure 105. In some exemplary embodiment, the cable clamp 120 may be electrically coupled to the electronic enclosure 105 via the cable shield 115 and the gasket 110. For example, for a shielded ethernet cable may include a braided shield around a plurality of wire conductors. Usually, the braided shield is covered with an insulative jacket, such as polyvinyl chloride or polyurethane. A portion of the insulative jacket may be removed, exposing the braided shield, which is then electrically couped to the cable clamp 120. In some exemplary embodiments, the cable clamp 120 may be the electrically coupled to the braided shield by clamping the cable 125 with the cable clamp 120 at the location of the exposed braided shield. Under this configuration, the cable clamp 120 and cable 125 can be configured such that the cable clamp 120 is electrically coupled to a shield or ground of the cable 125, thereby coupling any unwanted electromagnetic noise from the cable to an electrical ground, such as the engine block or the like. This configuration advantageously reduces electromagnetic interface that is coupled to the PCB or other electronics within the electronic enclosure 105.

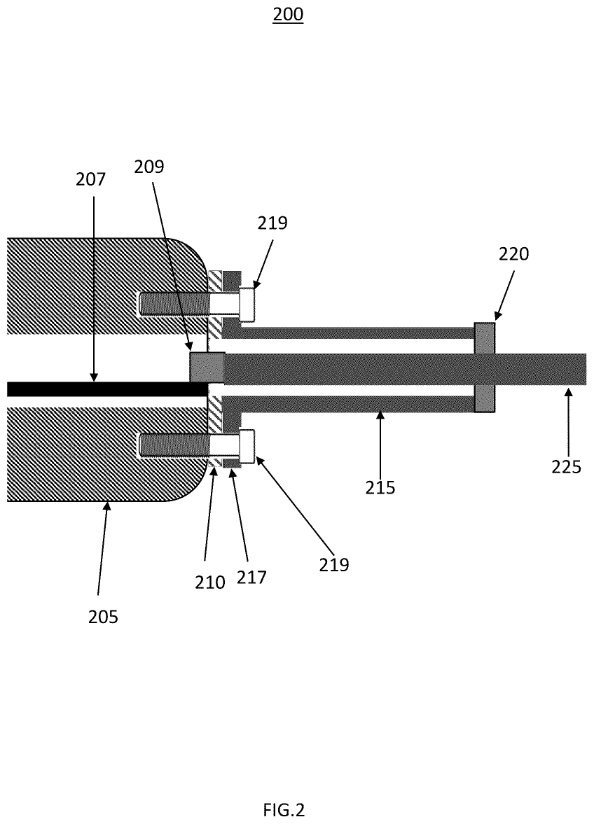

Turning now to FIG. 2, an cross section of an exemplary configuration 200 for an improved high voltage connector thermal, crash and vibration cable shield 215 is shown in accordance with various embodiments. The exemplary configuration 200 is illustrative of an electronics enclosure 205, a PCB 207, a cable shield 215, cable shield flange 217. a plurality of mechanical fasteners 219, a shield gasket 210, a cable clamp 220, a cable 225 and an electric connector 209.

In some exemplary embodiments, the electronics enclosure 205 can be a liquid cooled metallic structure configured to isolate the PCB 207 from environmental contamination from moisture, dust, electromagnetic interference, thermal energy and the like. In automotive applications, the electronic enclosure 205 can be configured to be mechanically and electrically coupled to an engine block or other engine compartment surface. In some exemplary embodiments, the electronic enclosure can include an electronic turbocharger controller and/or power supply.

The PCB 207 is configured to transmit and receive electrical signals and/or electrical currents to outside components via a cable 225. In some exemplary embodiments, the cable is a high current cable for conducting electrical current to an electric motor. Along with other electrical components, such as resistors, capacitors, diodes and integrated circuits, the PCB 207 can be configured with a connector 209 for mechanically coupling to a cable connector coupled to a cable 225. It is desirable to reduce vibration and movement of the cable connector in order to prevent degradation of connector contact point coatings and damage to the connector 209 affixed to the PCB 207. Typically the connector 209 has various conductive leads which are soldered into vias, or holes, formed in the PCB 207 in order to create a reliable electrical connection. However, these soldered connectors are susceptible to damage caused by external forces on the connector 209 which may break the leads, the connector 209 and/or the solder joints at the interface of the PCB 207. To accomplish this goal, a cable shield 215 with integrated cable clamp is configured to restrict movement of the cable 225 and to provide an environmental barrier between the ambient environment and the connector 209

The cable shield 215 can be mechanically affixed to the electronic enclosure 215 via one or more mechanical fasteners 219. In some exemplary embodiments, the mechanical fasteners can be positioned through holes in the cable shield flange 217 into threaded holes formed and/or tapped into the electronic enclosure 205. When fully seated into the threaded holes, the mechanical fasteners 219 apply a force on the cable shield flange 217 towards the electronic enclosure 205. In some exemplary embodiments, a shield gasket 210 may be positioned between the electronic enclosure 205 and the cable shield flange 217 such that a barrier to dust, dirt, moisture and thermal energy is formed between the cable shield 215, cable shield flange 217 and the electronic enclosure 205. The force generated by the mechanical fasteners 219 can retain the shield gasket 219 and/or compress the shield gasket 210 thereby enabling the environmental barrier.

The cable clamp 220 can be configured to apply clamping pressure to the cable 225 in order to reduce induced vibration at the connector 209 and to reduce lateral torque between the cable 225 and the connector 209. In some exemplary embodiments, the cable clamp 220 can be electrically coupled to a braided shield or other conductive barrier within the cable 225 in order to provide a ground connection from the conductive barrier to the electronic enclosure 205 or other ground point to prevent unwanted electromagnetic energy from reaching the PCB 207 and damaging the connector 209 or electronic components or corrupting the operation of the circuitry.

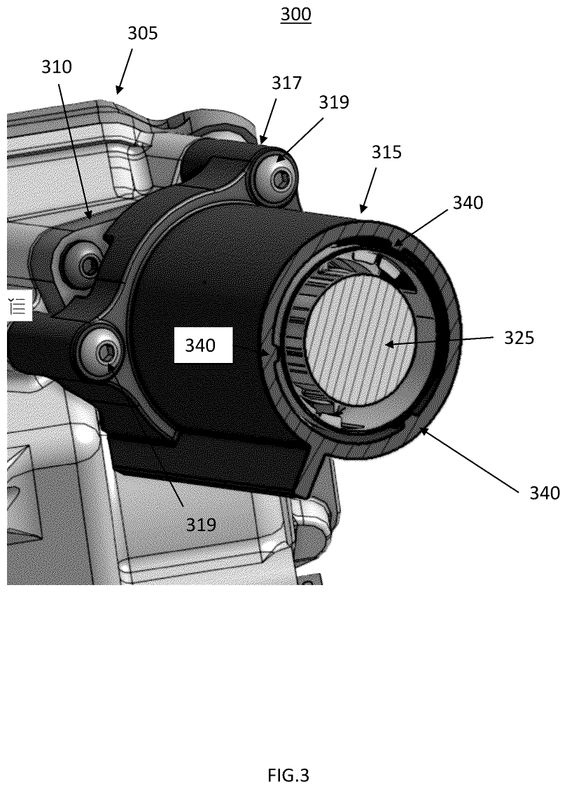

Turning now to FIG. 3, a cross sectional view 300 of the cable shield 315 for the improved high voltage connector thermal, crash and vibration cable shield 315 is shown in accordance with various embodiments. The exemplary cross sectional view 300 is illustrative of an electronics enclosure 305, a cable shield 315, cable shield flange 317. a plurality of mechanical fasteners 319, a shield gasket 310, a cable 325 and a plurality of retention ribs 340.

In order to further restrict cable movement, the cable shield 315 may be formed with one or more ribs 340 or protrusions formed within the cable shield 315. In the illustrated cross section view and exemplary embodiment is shown with three ribs 340 formed within the cable shield 315 in order to hold the cable 325. These ribs restrict cable movement, thereby restricting cable connector movement, reducing the probability of plating wear and/or connector damage. In some exemplary embodiments, the ribs are formed parallel to the length of the cable, or orthogonal to the cable shield flange 317, or can be formed perpendicular to the length of the cable, resulting in a required insertion force being applied to the cable during assembly. Parallel ribs can restrict cable movement in and out of the connector, and restriction rotational movement of the cable 325.

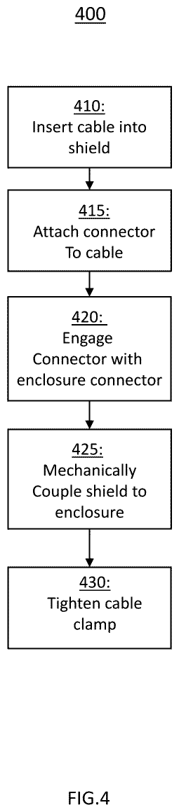

Turning now to FIG. 4, a flow diagram illustrating a non-limiting embodiment of a method 400 of providing an improved high voltage connector thermal, crash and vibration cable shield in accordance with the teachings of the present disclosure is shown.

The method 400 is first operative for inserting a cable into and through a cable shield. In some exemplary embodiments, the cable shield is configured as a tube having an opening at each end of the tube. The cable is inserted into a first opening until the cable protrude from the second opening. In some exemplary embodiments, the first opening is configured with a cable clamp and the second opening is configured with a cable shield flange. The internal dimensions of the cable shield correspond substantially to the outer dimensions of the cable. In some exemplary embodiments, the inner surface of the cable shield can include one or more ribs or extrusions to restrict rotational movement of the cable once the cable is inserted into the cable shield.

Once the cable has been inserted into the cable shield such that the cable extends from the second opening, a connector is attached 415 to the end of the cable extruding from the second opening of the cable shield. In some exemplary embodiments, the connector is attached to the cable after cable insertion through the cable shield and the internal dimensions of the cable shield are small than the exterior dimensions of the cable connector. In some exemplary embodiments where the cable connector dimensions are smaller than the interior dimensions of the cable shield, the cable connector can be connected to the cable before the cable is inserted into the cable shield.

Once the cable connector is installed on the cable and the cable with connector is protruding from the cable shield, the cable connector is engaged 420 with the PCB connector exposed from the electronic enclosure. In some exemplary embodiments, the PCB connector is electrically or communicatively coupled to the PCB by a cable interior to the electronic enclosure or by soldering the PCB connector directly to the PCB. In some exemplary embodiment the cable connector is a plastic connector which is press fit into a corresponding plastic PCB connector. Each of the PCB connector and the cable connector may include a portion of a locking mechanism, such as a spring loaded clip and locking extrusion for position assurance and engagement retention after installation engagement.

After the connectors are engaged, the cable shield can be slid over the connector interface and mechanically fastened 425 to the electronic enclosure. The mechanical fastening can be accomplished with bolts passing through holes in a cable shield flange and threaded and tightened into corresponding threaded holes in the electronic enclosure to create a rigid connection between the cable shield and the electronic enclosure. A gasket can be located between the electronic enclosure and the cable shield flange to provide additional environmental and/or thermal isolation between the connectors and the surrounding environment. In addition, gasket materials can be selected to improve or inhibit thermal and/or electrical conduction between the cable shield and the electronic enclosure. In some exemplary embodiments, an exterior surface of the cable shield can include threads for threading into a corresponding hole in the electronic enclosure having interior threads and exposing the electrical connector. In these embodiments no threaded fasteners would be used as the cable shield itself is threaded into the corresponding hole in the electronic enclosure.

Once the cable shield is rigidly affixed to the electronic enclosure, a cable clamp proximate to the first opening is tightened 430 on the cable near the first opening. The cable clamp can be a saddle clamp or the like and can be electrically coupled to a braided shield of the cable. The cable clamp restrains the cable at the location of the cable clamp in order to reduce vibration of the cable at the connector interface and to reduce other damaging physical movement of the cable.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It is understood that various changes may be made in the function and arrangement of elements described in an exemplary embodiment without departing from the scope of the present disclosure as set forth in the appended claims.

What is claimed is:

1. An electrical cable support and heat shield comprising;
a cable clamping device for clamping to a portion of an electrical cable; and
a rigid tubular sleeve having a connector end and a clamping end and an interior dimension configured to receive the electrical cable, wherein the connector end is mechanically coupled to a cooled structure and the clamping end is configured with the cable clamping device.

2. The electrical cable support and heat shield of claim 1 wherein a first electrical connector affixed to the electrical cable is mechanically coupled to a corresponding electrical connector within the cooled structure such that the electrical cable is communicatively coupled to an electronic component within the cooled structure.

3. The electrical cable support and heat shield of claim 1 wherein the cooled structure is a metallic electronic enclosure.

4. The electrical cable support and heat shield of claim 1 wherein the cooled structure is a liquid cooled structure.

5. The electrical cable support and heat shield of claim 1 wherein the rigid tubular sleeve includes a flange at the connector end and wherein the flange is mechanically coupled to the cooled structure with a plurality of threaded bolts each passing through a hole in the flange and threaded into a corresponding hole in the cooled structure.

6. The electrical cable support and heat shield of claim 1 wherein the cable clamping device is electrically coupled to a braided shield of the electrical cable and the rigid tubular sleeve is electrically coupled to the cooled structure.

7. The electrical cable support and heat shield of claim 1 wherein the rigid tubular sleeve further includes a plurality of ridges formed on an interior surface of the rigid tubular sleeve.

8. The electrical cable support and heat shield of claim 1 wherein the cooled structure encloses a motor controller and wherein the electrical cable conducts an electrical current between the motor controller and an electric motor.

9. The electrical cable support and heat shield of claim 1 further including an electrically conductive gasket located between the cooled structure and the rigid tubular sleeve.

10. An environmental management system including an electronic enclosure comprising:
a printed circuit board having a first electrical connector wherein the first electrical connector aligns with an opening in the electronic enclosure;
an electrical cable having a second electrical connector for coupling to the first electrical connector; and
a tubular cable shield having a flange end and a clamping end wherein the second electrical connector is positioned within the flange end and wherein the flange end is mechanically affixed over the opening in the electronic enclosure creating an environmental and thermal barrier around the second electrical connector and where the clamping end includes a cable clamp assembly for restraining the electrical cable.

11. The environmental management system including an electronic enclosure of claim 10 further including an electrically conductive gasket located between the flange end of the tubular cable shield and the electronic enclosure.

12. The environmental management system including an electronic enclosure of claim 10 wherein the electronic enclosure is a liquid cooled structure and wherein the tubular cable shield is thermally coupled to the electronic enclosure.

13. The environmental management system including an electronic enclosure of claim 10 wherein the cable clamp assembly restrains the electrical cable at least eight centimeters from the second electrical connector.

14. The environmental management system including an electronic enclosure of claim 10 wherein the cable clamp assembly and the electronic enclosure are both mechanically affixed to a common rigid support.

15. The environmental management system including an electronic enclosure of claim 10 wherein the cable clamp assembly and the electronic enclosure are both mechanically affixed to an engine block component.

16. The environmental management system including an electronic enclosure of claim 10 wherein the cable clamp assembly is electrically coupled to an electromagnetic shield of the electrical cable and wherein the cable clamp assembly is electrically coupled to the electronic enclosure.

17. The environmental management system including an electronic enclosure of claim 10 wherein the tubular cable shield further includes a plurality of protrusions formed on an interior surface of the tubular cable shield such that the plurality of protrusions restrict movement of the electrical cable.

18. The environmental management system including an electronic enclosure of claim 10 further including an electrically conductive gasket located between the electronic enclosure and the flange end of the tubular cable shield.

19. A method of providing an electrical cable support and heat shield comprising:
inserting an electrical cable through a tubular cable shield having a flange end and a cable clamping end;
affixing a first electrical connector onto the electrical cable protruding from the flange end of the tubular cable shield;
coupling the first electrical connector to a second electrical connector positioned in an opening in an electronics enclosure;
mechanically affixing the flange end of the tubular cable shield over the opening in the electronics enclosure such that an environmental a barrier is created around the first electrical connector and the second electrical connector; and
clamping the electrical cable with a cable clamp assembly affixed to the cable clamping end of the tubular cable shield such that the electrical cable is restrained by the cable clamp assembly.

20. The method of providing an electrical cable support and heat shield of claim 19 further including mechanically affixing the electronics enclosure and the cable clamp assembly to a rigid structure.
